(19) United States
(12) Patent Application Publication
(10) Pub. No.: US 2021/0373069 A1
(43) Pub. Date: Dec. 2, 2021

(54) SIGNAL TESTING DEVICE AND SIGNAL TESTING METHOD

(71) Applicant: Wiwynn Corporation, New Taipei City (TW)

(72) Inventors: Kuan-Wei Chen, New Taipei City (TW); Tzu-Yu Wei, New Taipei City (TW); Yi-Shian Chen, New Taipei City (TW); Yi-Tang Chen, New Taipei City (TW); Chi-Hsiang Hung, New Taipei City (TW); Ting-Kai Wang, New Taipei City (TW)

(73) Assignee: Wiwynn Corporation, New Taipei City (TW)

(21) Appl. No.: 16/932,861

(22) Filed: Jul. 20, 2020

(30) Foreign Application Priority Data
Jun. 2, 2020 (TW) 109118387

(51) Int. Cl. G01R 31/28; G01R 1/067

(52) U.S. Cl. CPC G01R 31/2806; G01R 1/06772

(57) ABSTRACT

A signal testing device and a signal testing method are provided. The method includes: obtaining, through a probe, a first frequency response corresponding to a test fixture and a device under test (DUT); obtaining, through the probe, a second frequency response corresponding to the test fixture; and generating a frequency response corresponding to the DUT according to the first frequency response, the second frequency response, a de-embedding algorithm, and an empirical mode decomposition algorithm.

### CROSS-REFERENCE TO RELATED APPLICATION

This application claims the priority benefit of Taiwan application serial no. 109118387, filed on Jun. 2, 2020. The entirety of the above-mentioned patent application is hereby incorporated by reference herein and made a part of this specification.

### BACKGROUND

### Technical Field

The disclosure relates to an electronic device and a method, and in particular to a signal testing device and a signal testing method suitable for measuring a frequency response of a device under test through a test fixture.

### Description of Related Art

Insertion loss of a printed circuit board (PCB) may significantly affect the performance of a high-frequency printed circuit board. When a printed circuit board is designed, a designer would reduce the insertion loss as much as possible to avoid reduction in the performance of the printed circuit board. Therefore, the designer needs to frequently carry out signal testing on the printed circuit board, and determines whether the layout or material of the printed circuit board needs to be adjusted or not according to a test result.

At present, signal testing devices conforming to industry standards are mostly used to measure the frequency response of printed circuit boards in the industry. However, the highest frequency supported by existing signal testing devices is only 40 gigahertz (GHz), and higher frequency signals cannot be measured. In addition, the existing signal testing devices require replacement of different probes when measuring signals at different frequencies.

### SUMMARY

The invention provides a signal testing device and a signal testing method which can test signals of 40 gigahertz or above and can test signals at different frequencies by using a same probe.

The signal testing device of the invention is suitable for measuring a frequency response of a device under test through a test fixture. The signal testing device includes a probe and a processor. The processor is coupled with the probe. The processor obtains a first frequency response corresponding to the test fixture and the device under test through the probe, obtains a second frequency response corresponding to the test fixture through the probe, and generates the frequency response of the device under test according to the first frequency response, the second frequency response, a de-embedding algorithm and an empirical mode decomposition algorithm.

In one embodiment of the invention, the processor generates a third frequency response corresponding to the device under test according to the first frequency response, the second frequency response and the de-embedding algorithm, and generates the frequency response according to the third frequency response and the empirical mode decomposition algorithm.

In one embodiment of the invention, the processor decomposes the third frequency response into a residual and a plurality of intrinsic mode function components according to the empirical mode decomposition algorithm, and generates the frequency response according to the residual and at least one of the plurality of intrinsic mode function components.

In one embodiment of the invention, at least one of the plurality of intrinsic mode function components includes: an N^{th} intrinsic mode function component to an M^{th} intrinsic mode function component of the plurality of intrinsic mode function components, where M is a quantity of the plurality of intrinsic mode function components, and N is a positive integer smaller than M.

In one embodiment of the invention, the processor generates the third frequency response according to the first frequency response and the empirical mode decomposition algorithm, generates a fourth frequency response according to the second frequency response and the empirical mode decomposition algorithm, and generates the frequency response according to the third frequency response, the fourth frequency response and the de-embedding algorithm.

In one embodiment of the invention, the processor decomposes the first frequency response into the residual and the plurality of intrinsic mode function components according to the empirical mode decomposition algorithm, and generates the third frequency response according to the residual and at least one of the plurality of intrinsic mode function components.

In one embodiment of the invention, at least one of the plurality of intrinsic mode function components includes: the N^{th} intrinsic mode function component to the M^{th} intrinsic mode function component of the plurality of intrinsic mode function components, where M is a quantity of the plurality of intrinsic mode function components, and N is a positive integer smaller than M.

In one embodiment of the invention, the empirical mode decomposition algorithm is a bi-dimensional empirical mode decomposition algorithm.

In one embodiment of the invention, a frequency range supported by the probe includes 0 Hz to 70 GHz.

The signal testing method of the invention is suitable for measuring a frequency response of a device under test through a test fixture. The signal testing method includes: obtaining, through a probe, a first frequency response corresponding to the test fixture and the device under test; obtaining, through the probe, a second frequency response corresponding to the test fixture; and generating the frequency response corresponding to the device under test according to the first frequency response, the second frequency response, a de-embedding algorithm, and an empirical mode decomposition algorithm.

Based on the above, the same probe can be used to measure the frequency response of the device under test at different frequencies (for example: a frequency exceeding 40 GHz) based on the de-embedding algorithm and the empirical mode decomposition algorithm.

### BRIEF DESCRIPTION OF THE DRAWINGS

FIG. 1 is a schematic diagram of a signal testing device in accordance with one embodiment of the invention.

FIG. 2 is a schematic diagram of the signal testing device generating a frequency response according to an empirical mode decomposition algorithm in accordance with one embodiment of the invention.

FIG. 3A is a schematic diagram of measurement of a frequency response of a test fixture and a device under test in accordance with one embodiment of the invention.

FIG. 3B is a schematic diagram of measurement of a frequency response of the test fixture in accordance with one embodiment of the invention.

FIG. 4 is a schematic diagram of a frequency response of the test fixture and the device under test and a frequency response of the test fixture in accordance with one embodiment of the invention.

FIGS. 5A and 5B are schematic diagrams of generation of the frequency response of the device under test according to a de-embedding algorithm and an empirical mode decomposition algorithm according to one embodiment of the invention.

FIGS. 6A and 6B are schematic diagrams of generation of the frequency response of the device under test according to the de-embedding algorithm and the empirical mode decomposition algorithm in accordance with another embodiment of the invention.

FIG. 7 is a schematic diagram of a signal testing method in accordance with one embodiment of the invention.

### DESCRIPTION OF THE EMBODIMENTS

To make the content of the invention easier to be understood, the following particular embodiments are examples whereby the invention may indeed be implemented. In addition, wherever possible, elements/components/steps with same reference numbers in the drawings and implementations represent same or similar parts.

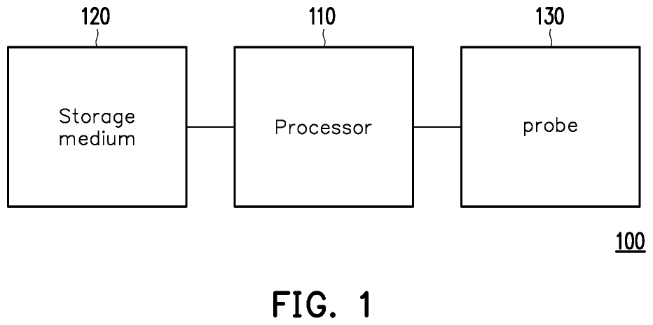

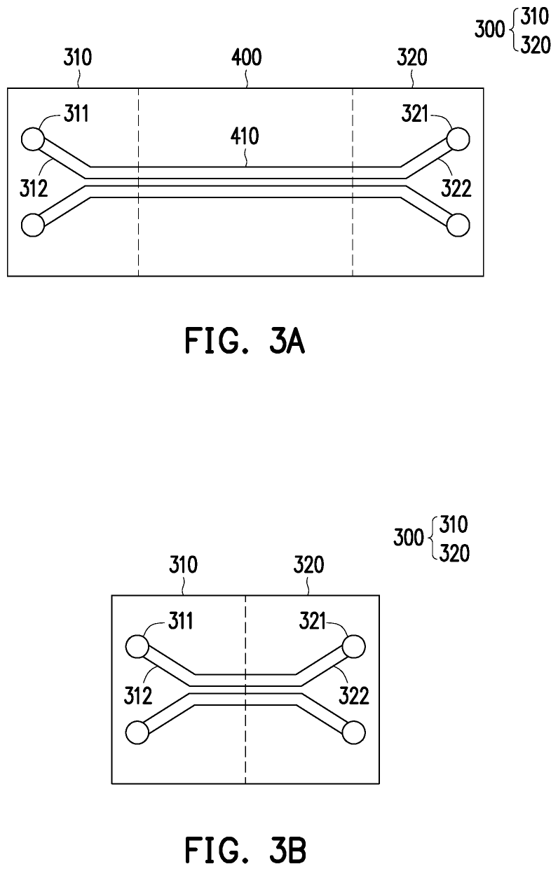

FIG. 1 is a schematic diagram of a signal testing device 100 in accordance with one embodiment of the invention. The signal testing device 100 may include a processor 110, a storage medium 120, and a probe 130. The signal testing device 100 is suitable for measuring a frequency response of a device under test (for example: a device under test shown in FIG. 3A) through a test fixture (for example: a test fixture 300 shown in FIG. 3A).

The processor 110, for example, is a central processing unit (CPU), or is another programmable general-purpose or special-purpose micro control unit (MCU), a microprocessor, a digital signal processor (DSP), a programmable controller, an application specific integrated circuit (ASIC), a graphics processing unit (GPU), an image signal processor (ISP), an image processing unit (IPU), an arithmetic logic unit (ALU), a complex programmable logic device (CPLD), a field programmable gate array (FPGA) or other similar elements or a combination of the foregoing elements. The processor 110 may be coupled to the storage medium 120 and the probe 130, and stores and executes a plurality of modules and various applications stored in the storage medium 120.

The storage medium 120 is, for example, any type of fixed or movable random access memory (RAM), a read-only memory (ROM), a flash memory, a hard disk drive (HDD), a solid state drive (SSD), or similar elements or a combination of the foregoing elements, and is configured to store a plurality of modules or various applications which may be executed by the processor 110.

The probe 130 may include a positive electrode and a negative electrode. If the frequency response of the device under test (for example a metal line) needs to be measured, the positive electrode of the probe 130 can be in contact with one end of the metal line by a user, and the negative electrode of the probe 130 is in contact with the other end of the metal line. The processor 110 can measure the frequency response of the metal line according to the positive electrode and the negative electrode of the probe 130. A frequency range supported by the probe 130 may include 0 Hz to 70 GHz, but the invention is not limited thereto.

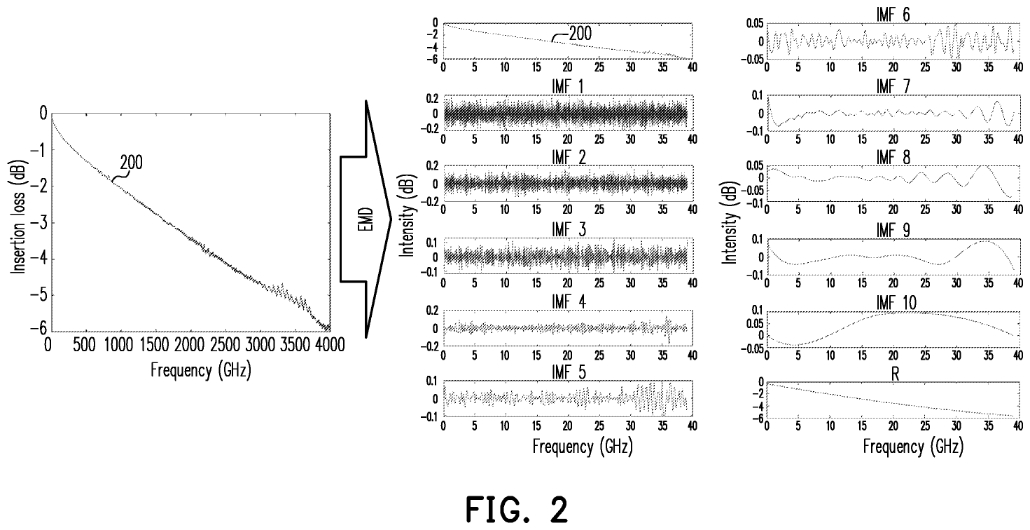

The signal testing device 100 can perform the empirical mode decomposition (EMD) algorithm on a frequency response to filter out noise (for example: nonlinear noise) of the frequency response and generate a new frequency response. FIG. 2 is a schematic diagram of the signal testing device 100 generating a frequency response according to the empirical mode decomposition algorithm in accordance with one embodiment of the invention. In the present embodiment, a frequency response 200 is assumed to be a frequency response containing noise.

For example, the frequency response 200 is irregularly jagged by noise in a high frequency range of 30 GHz to 40 GHz. To filter out the noise of the frequency response 200, the processor 110 can perform empirical mode decomposition on the frequency response 200 to generate a new frequency response.

In particular, the processor 110 can perform empirical mode decomposition on the frequency response 200 to decompose the frequency response 200 into a residual R and M intrinsic mode function (IMF) components, and M may be an optional positive integer. In the M intrinsic mode function components, a first intrinsic mode function component represents a component which is subjected to a sifting process by minimum times (namely once), and an M^{u}' intrinsic mode function component represents a component which is subjected to the sifting process by maximum times. In the present embodiment, M, for example (but not limited to), is 10, and thus, the M intrinsic mode function components may include IMF 1, IMF 2, IMF 3, IMF 4, IMF 5, IMF 6, IMF 7, IMF 8, IMF 9 and IMF 10 as shown in FIG. 2; IMF 1 is the component subjected to one-time sifting process, and IMF 10 is the component subjected to ten-time sifting process.

The processor 110 can generate a frequency response H(f) according to the residual R and at least one intrinsic mode function component in the M intrinsic mode function components, and the frequency response H(f) is equal to the frequency response 200 of which the noise is filtered out. In one embodiment, the processor 110 can generate the frequency response H(f) according to the residual R and an N^{th} intrinsic mode function component to an M^{th} intrinsic mode function component in the M intrinsic mode function components; N is a positive integer smaller than M. The frequency response H(f) may be a linear combination of the N^{th} intrinsic mode function component to the M^{th} intrinsic mode function component and the residual R. For example, M is assumed to be 10 and N is assumed to be 8, then the frequency response H(f) may be expressed as H(f)=a0·R+a1·(IMF 8)+a2·(IMF 9)+a3·(IMF 10), and a0, a2 and a3 are scalar quantities.

The signal testing device 100 can measure the frequency response of the device under test according to the de-embedding algorithm and the empirical mode decomposition algorithm. In particular, the processor 110 can obtain a frequency response corresponding to the test fixture and the device under test through the probe 130. FIG. 3A is a schematic diagram of measurement of the frequency response of the test fixture 300 and the device under test 400 according to one embodiment of the invention. The test fixture 300 may include a first fixture 310 and a second fixture 320. The device under test 400 may be coupled to the test fixture 300.

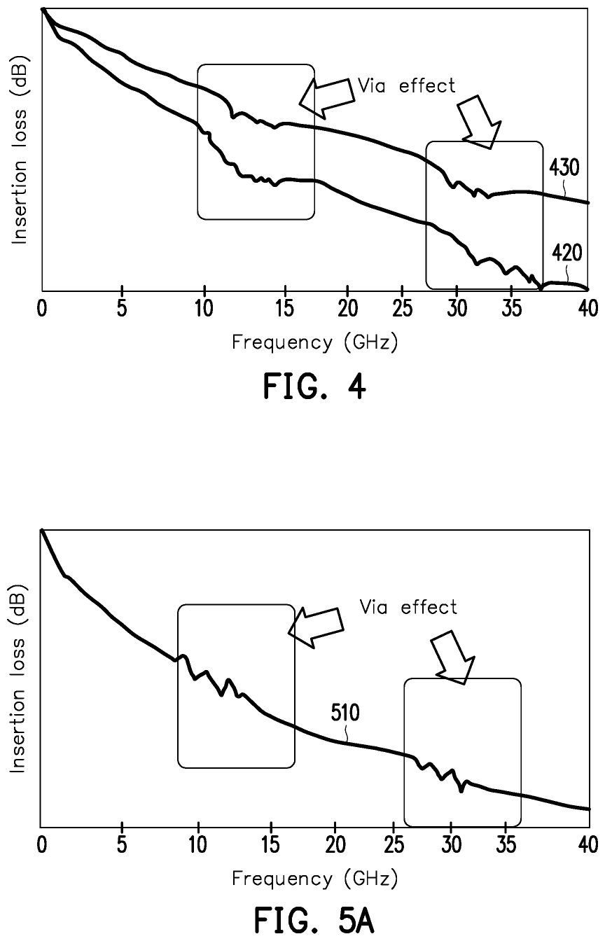

One end of a metal line 410 on the device under test 400 may be electrically connected to one end of a metal line 312 of the first fixture 310, and the other end of the metal line 410 may be electrically connected to a metal line 322 of the second fixture 320. In other words, the metal line 312 may be electrically connected to the metal line 322 through the metal line 410. The positive electrode and the negative electrode of the probe 130 may be respectively in contact with a test port 311 of the metal line 312 and a test port 321 of the metal line 322, so that the processor 110 can measure a frequency response through the probe 130 when the metal line 312, the metal line 410 and the metal line 322 are connected, as shown in FIG. 4. FIG. 4 is a schematic diagram of a frequency response 420 of the text fixture 300 and the device under test 400 and a frequency response 430 of the test fixture 300 according to one embodiment of the invention. Referring to FIG. 4, the processor 110 can measure the frequency response 420 through the probe 130 when the metal line 312, the metal line 410 and the metal line 322 are connected.

In another aspect, the processor 110 can obtain the frequency response corresponding to the test fixture through the probe 130. FIG. 3B is a schematic diagram of measurement of the frequency response of the test fixture 300 according to one embodiment of the invention. The first fixture 310 of the test fixture 300 may be coupled to the second fixture 320 of the test fixture 300. The metal line 312 on the first fixture 310 may be electrically connected to the metal line 322 on the second fixture 320. The positive electrode and the negative electrode of the probe 130 may be respectively in contact with the test port 311 of the metal line 312 and the test port 321 of the metal line 322, so that the processor 110 can measure the frequency response through the probe 130 when the metal line 312 and the metal line 322 are connected, as shown in FIG. 4. Referring to FIG. 4, the processor 110 can measure the frequency response 430 through the probe 130 when the metal line 312 and the metal line 322 are connected.

The frequency response 430 or the frequency response 420 may be distorted by interference of the noise. For example, in the present embodiment, the frequency response 430 or the frequency response 420 is distorted by influence of a via effect. In order to obtain an accurate frequency response of the device under test 400, the signal testing device 100 can correct the frequency response disturbed by the noise according to the de-embedding algorithm and the empirical mode decomposition algorithm.

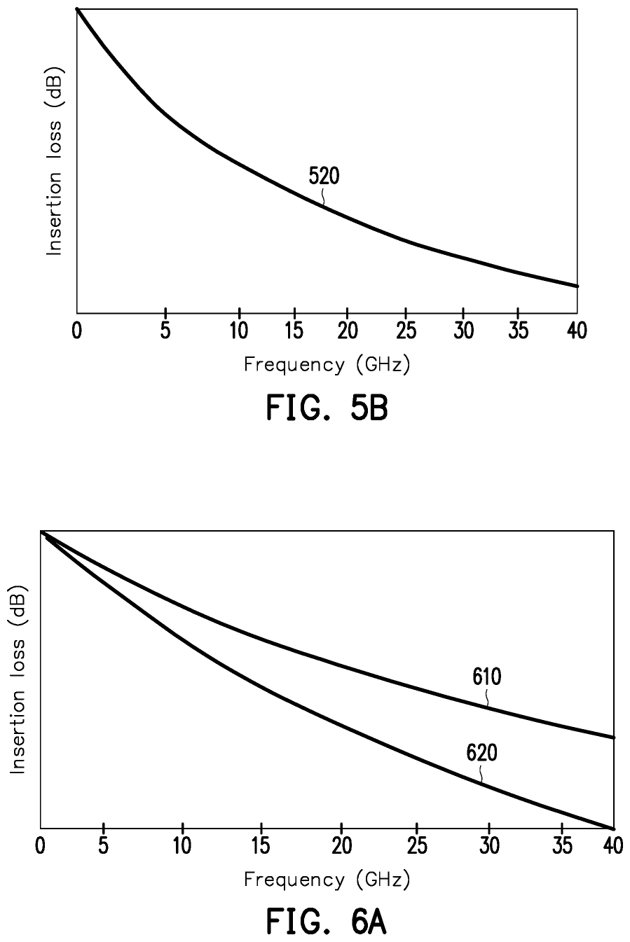

The signal testing device 100 may first perform the de-embedding algorithm and then perform the empirical mode decomposition algorithm to obtain the accurate frequency response of the device under test 400. FIGS. 5A and 5B are schematic diagrams of generation of a frequency response 520 of the device under test 400 according to the de-embedding algorithm and the empirical mode decomposition algorithm in accordance with one embodiment of the invention. In particular, the processor 110 of the signal testing device 100 can perform the de-embedding algorithm on the frequency response 430 and the frequency response 420 to generate the frequency response 510 corresponding to the device under test 400. As shown in FIG. 5A, although the processor 110 has generated the frequency response 510 corresponding to device under test 400 according to the frequency response 420 of both the test fixture 300 and the device under test 400 and the frequency response 430 of the test fixture 300, the frequency response 510 is still distorted by influence of the via effect.

To eliminate distortion of the frequency response 510, the processor 110 can perform the empirical mode decomposition algorithm on the frequency response 510 to generate a frequency response 520. For example, the processor 110 can perform empirical mode decomposition on the frequency response 510 to decompose the frequency response 510 into a residual R and M IMF components, and generate the frequency response 520 according to the residual R and an N^{th} intrinsic mode function component to an M^{th} intrinsic mode function component in the M intrinsic mode function components; M is an optional positive integer and N is a positive integer less than M. In the frequency response 520, the influences of the via effect have been filtered out. Thus, the frequency response 520 may be regarded as the accurate frequency response of the device under test 400.

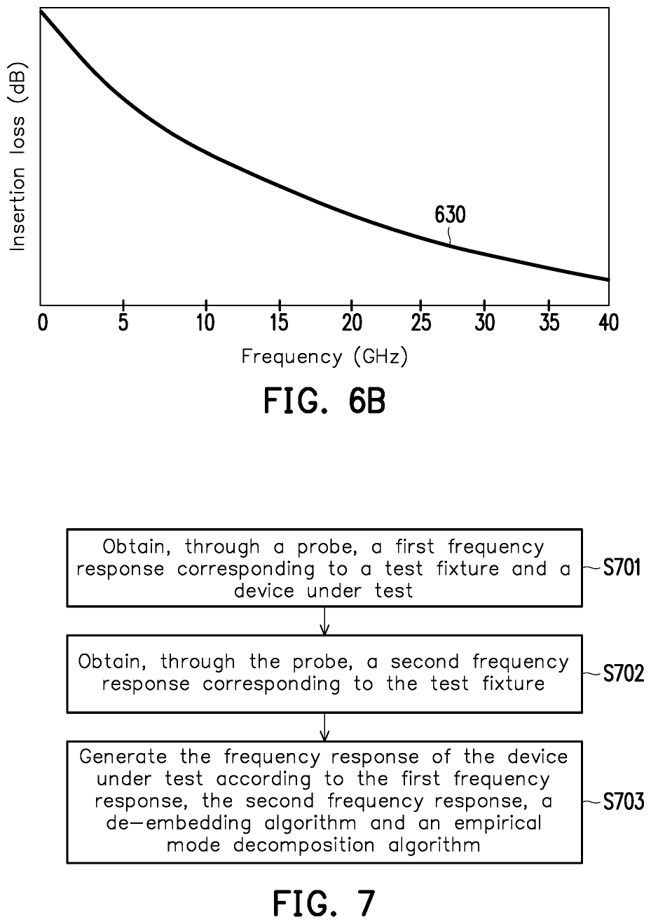

The signal testing device 100 may first perform the empirical mode decomposition algorithm and then perform the de-embedding algorithm to obtain the accurate frequency response of the device under test 400. FIGS. 6A and 6B are schematic diagrams of generation of a frequency response 630 of the device under test 400 according to the de-embedding algorithm and the empirical mode decomposition algorithm in accordance with another embodiment of the invention. In particular, the processor 110 of the signal testing device 100 can perform the empirical mode decomposition algorithm on the frequency response 430 to filter out noise from the frequency response 430 to produce the frequency response 610. Since the processor 110 has not implemented the de-embedding algorithm on the frequency response 430, a value on the frequency response 430 may be a complex. Accordingly, the processor 110 can decompose the frequency response 430 and generate the corresponding frequency response 610 by using a bi-dimensional empirical mode decomposition (BEMD) algorithm or a complex empirical mode decomposition (CEMD) algorithm.

For example, the processor 110 can perform bi-dimensional empirical mode decomposition on the frequency response 430 to decompose the frequency response 430 into a residual R and M IMF components, and generate the frequency response 610 according to the residual R and an N^{th} intrinsic mode function component to an M^{th} intrinsic mode function component in the M intrinsic mode function components; M is an optional positive integer and N is a positive integer less than M. Thus, the frequency response 610 may be regarded as the frequency response 430 of which the noise is filtered out.

In another aspect, the processor 110 of the signal testing device 100 can perform the empirical mode decomposition algorithm on the frequency response 420 to filter out noise from the frequency response 420 to generate a frequency response 620. Since the processor 110 has not implemented the de-embedding algorithm on the frequency response 420, a value on the frequency response 420 may be a complex. Accordingly, the processor 110 can decompose the frequency response 420 and generate the corresponding frequency response 620 by using the bi-dimensional empirical mode decomposition algorithm or the complex empirical mode decomposition algorithm.

For example, the processor 110 can perform bi-dimensional empirical mode decomposition on the frequency response 420 to decompose the frequency response 420 into a residual R and M IMF components, and generate the frequency response 620 according to the residual R and an N^{th} intrinsic mode function component to an M^{th} intrinsic mode function component of the M intrinsic mode function components; M is an optional positive integer and N is a positive integer less than M. Thus, the frequency response 620 may be regarded as the frequency response 420 of which the noise is filtered out.

After generating the frequency response 620 corresponding to the test fixture 300 and the device under test 400 and the frequency response 610 corresponding to the test fixture 300, the processor 110 can perform the de-embedding algorithm on the frequency response 610 and the frequency response 620 to generate a frequency response 630 corresponding to the device under test 400. The frequency response 630 may be regarded as the accurate frequency response of the device under test 400.

FIG. 7 is a schematic diagram of a signal testing method in accordance with one embodiment of the invention. The signal testing method is suitable for measuring the frequency response of the device under test through the test fixture and may be implemented by the signal testing device shown in FIG. 1. In step S701, a first frequency response corresponding to the test fixture and the device under test is obtained through the probe. In step S702, a second frequency response corresponding to the test fixture is obtained through the probe. In step S703, the frequency response of the device under test is generated according to the first frequency response, the second frequency response, a de-embedding algorithm, and an empirical mode decomposition algorithm.

In summary, the frequency response of the device under test at different frequencies (for example: a frequency response exceeding 40 GHz) can be measured according to the de-embedding algorithm and the empirical mode decomposition algorithm in the invention. Compared with the prior art, the frequency response measured by the invention is more accurate.

On the other hand, when signals in different frequency ranges are measured, application of different probes is avoided. Therefore, the manufacturing and using cost of the signal testing device can be reduced. Compared with the prior art based on singular value decomposition (SVD), the invention does not need time-frequency conversion, so that the operation time can be remarkably shortened.

What is claimed is:

1. A signal testing device, adapted for measuring a frequency response of a device under test through a test fixture, comprising:
a probe; and
a processor, coupled to the probe, wherein the processor obtains a first frequency response corresponding to the test fixture and the device under test through the probe, obtains a second frequency response corresponding to the test fixture through the probe and generates the frequency response of the device under test according to the first frequency response, the second frequency response, a de-embedding algorithm and an empirical mode decomposition algorithm.

2. The signal testing device according to claim 1, wherein the processor generates a third frequency response corresponding to the device under test according to the first frequency response, the second frequency response and the de-embedding algorithm, and generates the frequency response according to the third frequency response and the empirical mode decomposition algorithm.

3. The signal testing device according to claim 2, wherein the processor decomposes the third frequency response into a residual and a plurality of intrinsic mode function components according to the empirical mode decomposition algorithm, and generates the frequency response according to the residual and at least one of the plurality of intrinsic mode function components.

4. The signal testing device according to claim 3, wherein the at least one of the plurality of intrinsic mode function components comprises: an N^{th} intrinsic mode function component to an M^{th} intrinsic mode function component of the plurality of intrinsic mode function components, wherein M is a quantity of the plurality of intrinsic mode function components, and N is a positive integer smaller than M.

5. The signal testing device according to claim 1, wherein the processor generates a third frequency response according to the first frequency response and the empirical mode decomposition algorithm, generates a fourth frequency response according to the second frequency response and the empirical mode decomposition algorithm, and generates the frequency response according to the third frequency response, the fourth frequency response and the de-embedding algorithm.

6. The signal testing device according to claim 5, wherein the processor decomposes the first frequency response into a residual and a plurality of intrinsic mode function components according to the empirical mode decomposition algorithm, and generates the third frequency response according to the residual and at least one of the plurality of intrinsic mode function components.

7. The signal testing device according to claim 6, wherein the at least one of the plurality of intrinsic mode function components comprises: an N^{th} intrinsic mode function component to an M^{th} intrinsic mode function component of the plurality of intrinsic mode function components, wherein M is a quantity of the plurality of intrinsic mode function components, and N is a positive integer smaller than M.

8. The signal testing device according to claim 5, wherein the empirical mode decomposition algorithm is a bi-dimensional empirical mode decomposition algorithm.

9. The signal testing device according to claim 1, wherein a frequency range supported by the probe comprises 0 Hz to 70 GHz.

10. A signal testing method, adapted for measuring a frequency response of a device under test through a test fixture, comprising:
obtaining, through a probe, a first frequency response corresponding to the test fixture and the device under test;
obtaining, through the probe, a second frequency response corresponding to the test fixture; and
generating the frequency response of the device under test according to the first frequency response, the second frequency response, a de-embedding algorithm and an empirical mode decomposition algorithm.
